(19) United States
(12) Patent Application Publication
(10) Pub. No.: US 2026/0181984 A1
(43) Pub. Date: Jun. 25, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); CHEUNG CHENG, HSINCHU CITY (TW)

(21) Appl. No.: 18/991,778

(22) Filed: Dec. 23, 2024

(51) Int. Cl. H10D 64/00; H01L 21/3205; H10D 62/40; H10D 64/66

(52) U.S. Cl. CPC H10D 64/117; H10D 62/402; H10D 64/112; H10D 64/667; H10P 14/416

(57) ABSTRACT

A semiconductor device and method of manufacturing the same are provided. The semiconductor device includes a substrate, a gate electrode, a source/drain contact, a first field plate, and a second field plate. The gate electrode is disposed on the substrate. The source/drain contact is disposed on the substrate. The first field plate and the second field plate are disposed between the source/drain contact and the gate electrode. The first field plate is configured to receive a voltage of a first electrical polarity, and the second field plate is configured to receive a voltage of a second electrical polarity different from the first electrical polarity.

### BACKGROUND

Technological advances in semiconductor integrated circuit (IC) materials, design, processing, and manufacturing have enabled the continual reduction in size of IC devices, where each generation has smaller and more complex circuits than the previous generation.

As semiconductor circuits composed of devices such as metal-oxide-semiconductor field-effect transistors (MOSFETs) are adapted for high voltage applications, such as in lateral diffusion metal-oxide-semiconductor (LDMOS) devices, problems arise with respect to decreasing voltage performance as the downscaling continues with advanced technologies. Therefore, a new semiconductor device is required.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor device, in accordance with some embodiments of the present disclosure.

FIG. 2 illustrates a cross-sectional view of a semiconductor device, in accordance with some embodiments of the present disclosure.

FIG. 3 illustrates a cross-sectional view of a semiconductor device, in accordance with some embodiments of the present disclosure.

FIG. 4 illustrates a cross-sectional view of a semiconductor device, in accordance with some embodiments of the present disclosure.

FIG. 5A, FIG. 5B, FIG. 5C, FIG. 5D, and FIG. 5E illustrate various stages of manufacturing a semiconductor device, in accordance with some embodiments of the present disclosure.

FIG. 6 is a flow chart illustrating a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may be also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and the attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In some embodiments, semiconductor devices 100a to 100d are provided. Each of the semiconductor devices 100a to 100d can be a medium or high voltage semiconductor device. Each of the semiconductor devices 100a to 100d can be an n type high-voltage device, but the disclosure is not limited thereto. In some embodiments, each of the semiconductor devices 100a to 100d can be referred to as a laterally-diffused MOS (LDMOS) transistor device, a middle-voltage laterally-diffused MOS (MV LDMOS) transistor device, a high-voltage laterally-diffused MOS (HV LDMOS) transistor device, a middle-voltage extended-drain MOS (MV EDMOS) transistor device, a high-voltage extended-drain MOS (HV EDMOS) transistor device, or any other device.

In some embodiments of the present disclosure, the semiconductor device includes field plates configured to receive voltages of different electrical polarities (e.g., positive bias (or positive voltage) and negative bias (or negative voltage)), which can increase the transmission path of carriers (e.g., electrons and/or holes) between source/drain features. Therefore, a slower swing can be achieved, which can be applied to some electronic devices, such as organic light-emitting diode (OLED) or other suitable devices.

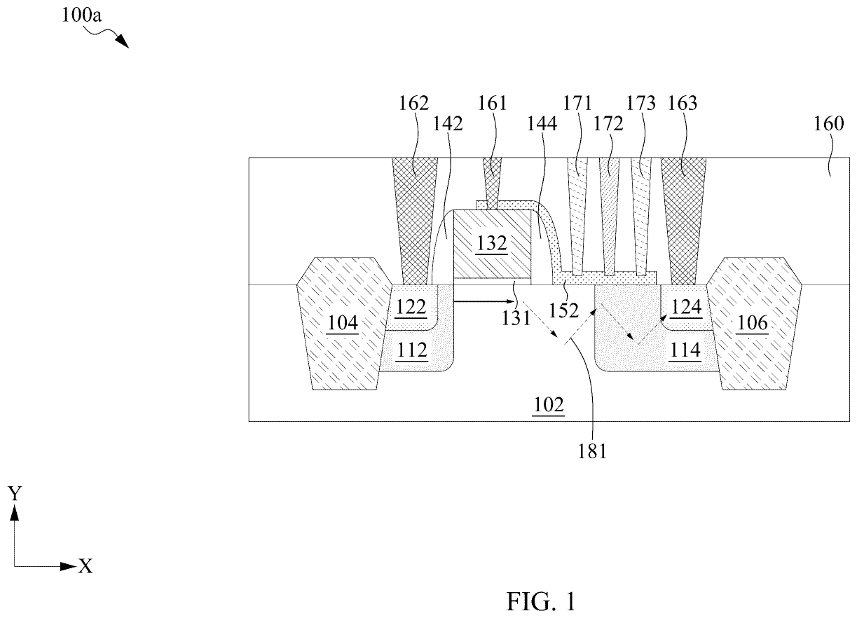

FIG. 1 illustrates a cross-sectional view of a semiconductor device 100a, in accordance with some embodiments of the present disclosure.

In some embodiments, the semiconductor device 100a includes a substrate 102. The substrate 102 includes a semiconductor substrate, such as a bulk semiconductor, a semiconductor-on-insulator (SOI) substrate, or the like, which may be doped (e.g., with a p type or an n type dopant) or undoped. The substrate 102 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate includes a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 102 may have a multilayer structure, or the substrate 102 may include a multilayer compound semiconductor structure.

In some embodiments, the substrate 102 includes a well region with a first conductive type (e.g., p-type). In some embodiments, the well region can be referred to as a high-voltage n type well (HVNW) or a high-voltage p type well (HVPW).

In some embodiments, the semiconductor device 100a includes isolation structures 104 and 106. Each of the isolation structures 104 and 106 is disposed within the substrate 102 and spaced apart from each other in a cross-sectional view. In other embodiments, the isolation structures 104 and 106 may include a local oxidization of silicon (LOCOS) structure, or any other suitable isolation structures, such as a shallow trench isolation (STI).

In some embodiments, the semiconductor device 100a includes lightly doped regions 112 and 114. The lightly doped regions 112 and 114 are disposed within the substrate 102. In some embodiments, each the lightly doped regions 112 and 114 has a second conductive type (e.g., n-type) different from the first conductive type. The lightly doped regions 112 and 114 can be referred to as a lightly doped drain (LDD) or a lightly doped source (LDS).

In some embodiments, the semiconductor device 100a includes doped regions 122 and 124. The doped region 122 is disposed within or surrounded by the lightly doped region 112. The doped region 124 is disposed within or surrounded by the lightly doped region 114. In some embodiments, each the doped regions 122 and 124 has the second conductive type (e.g., n-type) and has a dopant concentration greater than that of the lightly doped region 112 (or lightly doped region 114). In some embodiments, the doped regions 122 and 124 can function as source/drain features. For example, the doped region 122 can function as a source, and the doped region 124 can function as a drain. In this disclosure, source/drain feature(s) may refer to a source or a drain, individually or collectively dependent upon the context.

In some embodiments, the semiconductor device 100a includes a gate dielectric 131. The gate dielectric 131 may have a single layer or a multi-layer structure. In some embodiments, the gate dielectric 131 is a multi-layer structure that includes an interfacial layer and a high-k (dielectric constant greater than 4) dielectric layer. The interfacial layer can include dielectric material such as silicon oxide, silicon nitride, silicon oxynitride, other dielectric material, or a combination thereof. The high-k dielectric layer can include high-k dielectric material such as HfO₂, HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

In some embodiments, the semiconductor device 100a includes a gate electrode 132. The gate electrode 132 is disposed on the gate dielectric 131. The doped regions 122 and 124 are disposed on different sides of the gate electrode 132. The gate electrode 132 includes polysilicon, silicon-germanium, and at least one metallic material including elements and compounds such as molybdenum, copper, tungsten, titanium, tantalum, titanium nitride, tantalum nitride, nickel silicide, cobalt silicide, or other suitable conductive materials known in the art. In some embodiments, the gate electrode 132 includes a work function metal layer that provides a metal gate with an n type-metal work function or p type-metal work function. The p type-metal work function materials include materials such as ruthenium, palladium, platinum, cobalt, nickel, conductive metal oxide, or other suitable materials. The n type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device 100a includes spacers 142 and 144. The spacers 142 and 144 are disposed on two opposite sides of the gate electrode 132. Each of the spacers 142 and 144 includes a single layer structure or a multilayered structure. Each of the spacers 142 and 144 includes silicon oxide, silicon nitride, silicon oxynitride, other dielectric material, or a combination thereof.

In some embodiments, the semiconductor device 100a includes an etch stop layer 152. In some embodiments, the etch stop layer 152 extends from an upper surface of the gate electrode 132 to the upper surface of the substrate 102. The etch stop layer 152 covers the gate electrode 132, the spacer 144, and the substrate 102. In some embodiments, the etch stop layer 152 includes a dielectric material, such as silicon oxide, silicon nitride, silicon oxynitride, other dielectric material, or a combination thereof.

In some embodiments, the semiconductor device 100a includes an interlayer dielectric (ILD) 160. The ILD 160 may cover the substrate 102, the gate electrode 132, and the etch stop layer 152. The ILD 160 may include a dielectric material, such as an oxide-containing material or other suitable materials. The oxide-containing material may include phosphosilicate glass (PSG), tetraethylorthosilicate (TEOS) oxide, un-doped silicate glass, silicon dioxide, doped silicon dioxide such as borophosphosilicate glass (BPSG), fused silica glass (FSG), boron doped silicon glass (BSG), another suitable dielectric material, or a combination thereof.

In some embodiments, the semiconductor device 100a includes conductive contacts 161, 162, and 163. The conductive contact 161 is disposed on and electrically connected to the gate electrode 132. The conductive contact 161 penetrates at least a portion of the ILD 160 and the etch stop layer 152. The conductive contact 162 (or source/drain contact) is disposed on and electrically connected to the doped region 122. The conductive contact 162 penetrates at least a portion of the ILD 160. The conductive contact 163 (or source/drain contact) is disposed on and electrically connected to the doped region 124. The conductive contact 163 penetrates at least a portion of the ILD 160. The conductive contacts 161, 162, and 163 include a conductive material, such as copper, titanium, tungsten, silver, aluminum, titanium aluminum alloy, titanium aluminum nitride, tantalum carbide, tantalum carbon nitride, tantalum silicon nitride, manganese, zirconium, titanium nitride, tungsten nitride, tantalum nitride, ruthenium, or a combination thereof. Although FIG. 1 illustrates that the conductive contacts 161, 162, and 163 are within the same cross-section, it should be noted conductive contacts 161, 162, and 163 may also be located at different cross-sections, allowing for some of the conductive contacts 161, 162, and/or 163 to be omitted from a cross-sectional view.

In some embodiments, the semiconductor device 100a includes field plates 171, 172, and 173. The field plates 171, 172, and 173 are disposed between the conductive contact 161 (or gate electrode 132) and the conductive contact 163. The field plate 172 is disposed between the field plates 171 and 173. The field plate 171 is closer to the conductive contact 161 (or gate electrode 132) than the field plate 172 is. The field plate 173 is closer to the conductive contact 163 than the field plate 172 is. In some embodiments, the field plate 171 is free from vertically overlapping the lightly doped region 114 or free from overlapping the lightly doped region 114 along the Y direction.

In some embodiments, the field plates 171, 172, and 173 are configured to control the electric filed. For example, the field plates 171, 172, and 173 are configured to increase the transmission path of carriers (e.g., electrons or holes) between the lightly doped regions 112 and 114. In some embodiments, abutting two of the field plates 171, 172, and 173 are configured to receive voltages of different electrical polarities. For example, the field plate 171 is configured to receive a negative voltage (or negative bias), the field plate 172 is configured to receive a positive voltage (or positive bias), and the field plate 173 is configured to receive a negative voltage. In some embodiments, the field plates 171 and 173 are configured to receive the same voltage (or the same supply voltage or the same power).

In this condition, carries can follow a transmission pattern of approaching and escaping from the upper surface of the substrate 102, resulting in a longer transmission path.

In some embodiments, at least two field plates, receiving voltages of different electrical polarities, are disposed over the lightly doped region 114, thereby achieving a slower swing. For example, the field plates 172 and 173 vertically overlap the lightly doped region 114 or overlap the lightly doped region 114 along the Y direction.

In some embodiments, the conductive contact 161 (or gate electrode 132) and the field plate 171, which is the field plate closest to the conductive contact 161 (or gate electrode 132), are configured to receive voltages of different electrical polarities resulting in a longer transmission path of carriers. For example, the conductive contact 161 is configured to receive a positive voltage, and the field plate 171 is configured to receive a negative voltage. In some embodiments, the conductive contact 163 and the field plate 173 are configured to receive voltages of different electrical polarities. For example, the conductive contact 163 is configured to receive a positive voltage, and the field plate 173 is configured to receive a negative voltage resulting in a longer transmission path of carriers.

As shown in FIG. 1, carriers can be transmitted along a path 181. In some embodiments, the abutting two of the conductive contact 161, the field plates 171, 172, and 173, and the conductive contact 163 receive voltages of different electrical polarities. In this condition, a modified electrical field can cause the carriers to follow a transmission pattern of approaching and escaping from the upper surface of the substrate 102. Thus, the path 181 may include a substantial zigzag path. That is, the transmission path of carriers between the doped regions 122 and 124 is increased, resulting in a slower swing. In a comparative example, a diode may be used to achieve a higher swing performance. However, the diode may occupy additional space and adversely affect the miniaturization of devices. In this embodiment, the space for accommodating the aforementioned diode can be omitted. Therefore, the semiconductor device 100a can have a smaller dimension compared to comparative examples.

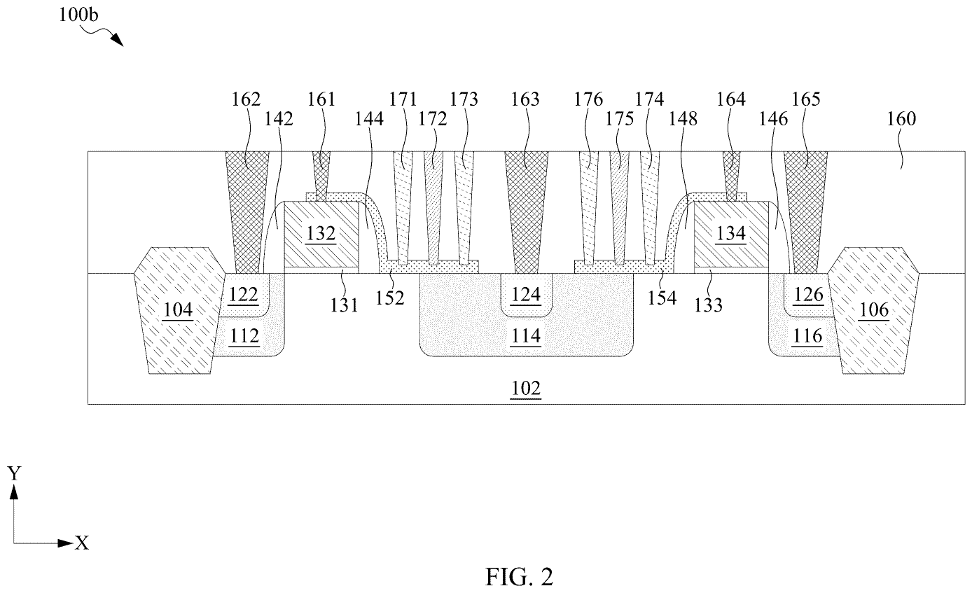

FIG. 2 illustrates a cross-sectional view of a semiconductor device 100b, in accordance with some embodiments of the present disclosure. In some embodiments, the semiconductor device 100b has a structure similar to that of the semiconductor device 100a, and one of the differences between them is that the semiconductor device 100b includes a common drain structure.

In some embodiments, the semiconductor device 100b further includes a lightly doped region 116. The lightly doped region 116 is disposed within the substrate 102. In some embodiments, the lightly doped regions 112 and 116 are disposed on two opposite sides of the lightly doped region 114. The lightly doped region 116 has the second conductive type (e.g., n-type). The lightly doped region 116 can function as the LDD or LDS.

In some embodiments, the semiconductor device 100b further includes a doped region 126. The doped region 126 is disposed within or surrounded by the lightly doped region 116. In some embodiments, the doped region 126 has the second conductive type (e.g., n-type). In some embodiments, the doped region 126 can function as source/drain features. For example, each the doped regions 122 and 126 can function as a source, and the doped region 124 can function as a common drain.

In some embodiments, the semiconductor device 100b further includes a gate dielectric 133. The gate dielectric 133 may have a single layer or a multi-layer structure. In some embodiments, the gate dielectric 133 is a multi-layer structure that includes an interfacial layer and a high-k (dielectric constant greater than 4) dielectric layer. In some embodiments, the material of the gate dielectric 133 is the same as or similar to that of the gate dielectric 131.

In some embodiments, the semiconductor device 100b further includes a gate electrode 134. The gate electrode 134 is disposed on the gate dielectric 133. The doped regions 124 and 126 are disposed on different sides of the gate electrode 134. The gate electrode 134 includes polysilicon, silicon-germanium, and at least one metallic material including elements and compounds such as Mo, Cu, W, Ti, Ta, TiN, TaN, NiSi, CoSi, or other suitable conductive materials known in the art. In some embodiments, the material of the gate electrode 134 is the same as or similar to that of the gate electrode 132.

In some embodiments, the semiconductor device 100b further includes spacers 146 and 148. The spacers 146 and 148 are disposed on two opposite sides of the gate electrode 134. Each of the spacers 146 and 148 includes a single layer structure or a multilayered structure. Each of the spacers 146 and 148 includes silicon oxide, silicon nitride, silicon oxynitride, other dielectric material, or a combination thereof.

In some embodiments, the semiconductor device 100b further includes an etch stop layer 154. In some embodiments, the etch stop layer 154 extends from an upper surface of the gate electrode 134 to the upper surface of the substrate 102. The etch stop layer 154 covers the gate electrode 134, spacer 148, and the substrate 102. In some embodiments, the etch stop layer 154 includes a dielectric material, such as silicon oxide, silicon nitride, silicon oxynitride, other dielectric material, or a combination thereof.

In some embodiments, the semiconductor device 100b further includes conductive contacts 164 and 165. The conductive contact 164 is disposed on and electrically connected to the gate electrode 134. The conductive contact 164 penetrates at least a portion of the ILD 160 and the etch stop layer 154. The conductive contact 165 is disposed on and electrically connected to the doped region 126. The conductive contact 165 penetrates at least a portion of the ILD 160. The conductive contacts 164 and 165 include a conductive material, such as Cu, Ti, W, Ag, Al, TiAl, TiAlN, TaC, TaCN, TaSiN, Mn, Zr, TiN, WN, TaN, Ru, or a combination thereof.

In some embodiments, the semiconductor device 100b further includes field plates 174, 175, and 176. The field plates 174, 175, and 176 are disposed between the conductive contact 164 (or gate electrode 134) and the conductive contact 163. The field plate 175 is disposed between the field plates 174 and 176. In some embodiments, abutting two of the field plates 174, 175, and 176 are configured to receive voltages of different electrical polarities. For example, the field plate 174 is configured to receive a negative voltage, the field plate 175 is configured to receive a positive voltage, and the field plate 176 is configured to receive a negative voltage. In some embodiments, the field plates 174, 175, and 176 are configured to increase the transmission path of carriers (e.g., electrons or holes) between the lightly doped regions 114 and 116.

In some embodiments, at least two field plates, receiving voltages of different electrical polarities, are disposed over the lightly doped region 114 and disposed between the doped regions 124 and 126, thereby achieving a slower swing. For example, the field plates 175 and 176 vertically overlap the lightly doped region 114 or overlap the lightly doped region 114 along the Y direction.

In some embodiments, the conductive contact 164 (or gate electrode 134) and the field plate 174 are configured to receive voltages of different electrical polarities. For example, the conductive contact 164 is configured to receive a positive voltage, and the field plate 174 is configured to receive a negative voltage.

In this embodiment, a modified electrical field can cause the carriers to follow a transmission pattern of approaching and escaping from the upper surface of the substrate 102. Thus, the transmission path of carriers between the doped regions 124 and 126 is increased, thereby achieving a slower swing.

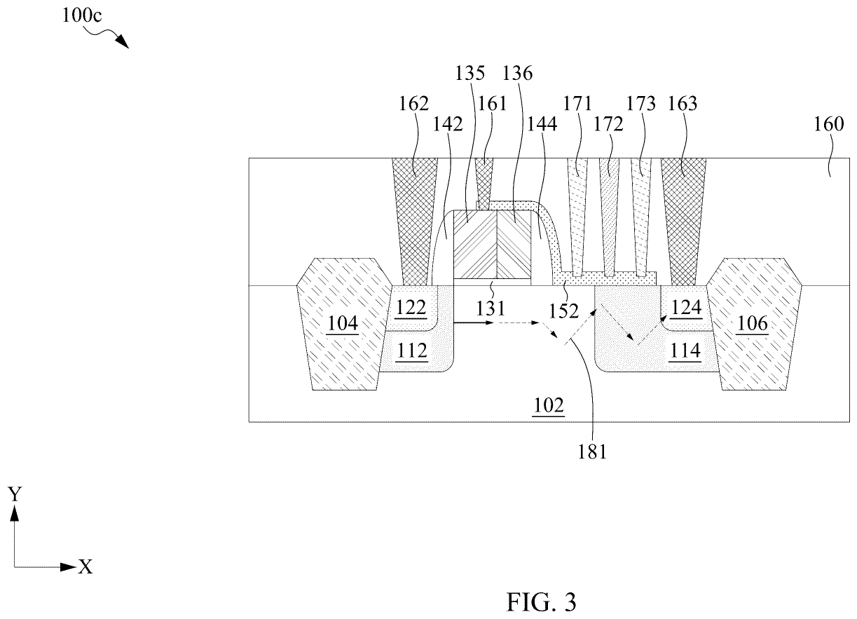

FIG. 3 illustrates a cross-sectional view of a semiconductor device 100c, in accordance with some embodiments of the present disclosure. In some embodiments, the semiconductor device 100c has a structure similar to that of the semiconductor device 100a, and one of the differences between them is that the semiconductor device 100c includes a gate electrode including work function metal layers with different conductive types.

In some embodiments, the semiconductor device 100c includes work function structures 135 and 136. The work function structures 135 and 136 can function as a gate. Each of the work function structures 135 and 136 includes one or more work function layers. The work function structure 136 is closer to the conductive contact 163 (or doped region 124) than the work function structure 135 is. In some embodiments, the work function structure 135 abuts or is in contact with the work function structure 136. For example, the lateral surface of the work function structure 135 may abut or be in contact with the work function structure 136.

In some embodiments, the work function structures 135 and 136 are configured to provide the gate with n-type-metal work function and p type-metal work function. For example, the work function structure 135 provides a metal gate with an n type-metal work function, and the work function structure 136 provides a metal gate with an p type-metal work function. In some embodiments, the work function structure 135 includes n type-metal work function materials, such as hafnium zirconium, titanium, tantalum, aluminum, metal carbides (e.g., hafnium carbide, zirconium carbide, titanium carbide, and aluminum carbide), aluminides, or other suitable materials. In some embodiments, the work function structure 136 includes p type-metal work function materials, such as ruthenium, palladium, platinum, cobalt, nickel, conductive metal oxide, or other suitable materials.

In some embodiments, the work function structures 135 and 136 are configured to adjust or modify the threshold voltage of the semiconductor device 100c. In some embodiments, the work function structure 136 may be configured to reduce the velocity of carriers, thereby achieving a slower swing.

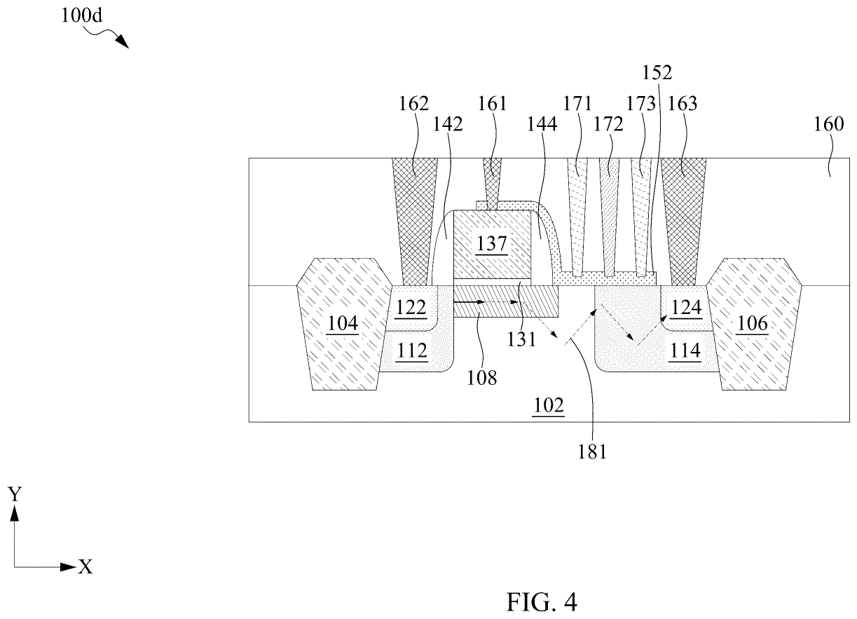

FIG. 4 illustrates a cross-sectional view of a semiconductor device 100d, in accordance with some embodiments of the present disclosure. In some embodiments, the semiconductor device 100d has a structure similar to that of the semiconductor device 100a, and one of the differences between them is that the semiconductor device 100d further includes a carrier-transmission barrier layer 108 and a gate electrode 137.

In some embodiments, the carrier-transmission barrier layer 108 is disposed within the substrate 102. In some embodiments, the carrier-transmission barrier layer 108 is disposed between the doped regions 122 and 124. In some embodiments, the carrier-transmission barrier layer 108 is disposed between the lightly doped regions 112 and 114. In some embodiments, the gate electrode 137 vertically overlaps the carrier-transmission barrier layer 108 or overlap the carrier-transmission barrier layer 108 along the Y direction. In some embodiments, the spacer 144 vertically overlaps the carrier-transmission barrier layer 108 or overlap the carrier-transmission barrier layer 108 along the Y direction. In some embodiments, a portion of the carrier-transmission barrier layer 108 is free from vertically overlapping the gate electrode 137. In some embodiments, the dimension (e.g., the width along the X direction) of the carrier-transmission barrier layer 108 is greater than that of the gate electrode 137. In some embodiments, the carrier-transmission barrier layer 108 is free from vertically overlapping the field plate 171.

In some embodiments, the carrier-transmission barrier layer 108 is configured to reduce the mobility of carriers, such as slowing down the carrier velocity as they move through the channel region and/or drift region. In some embodiments, the carrier-transmission barrier layer 108 includes an amorphous semiconductor material. In some embodiments, the carrier-transmission barrier layer 108 includes amorphous silicon (a-Si), amorphous germanium (a-Ge), amorphous silicon carbide (a-SiC), amorphous germanium (a-SiGe), amorphous gallium arsenide (a-GaAs), amorphous indium gallium phosphide (a-GaInP), amorphous indium gallium arsenide (a-InGaAs), amorphous gallium nitride (a-GaN), or other suitable materials.

In some embodiments, the carrier-transmission barrier layer 108 includes a polycrystalline semiconductor material. In some embodiments, the carrier-transmission barrier layer 108 includes polysilicon (or polycrystalline silicon), polygermanium (or polycrystalline germanium), polysilicon silicon carbide (poly-SiC), polysilicon germanium (poly-SiGe), polycrystalline gallium arsenide (poly-GaAs), polycrystalline indium gallium phosphide (poly-GaInP), polycrystalline indium gallium arsenide (poly-InGaAs), polycrystalline gallium nitride (poly-GaN), or other suitable materials.

In some embodiments, the gate electrode 137 is disposed over the carrier-transmission barrier layer 108. In some embodiments, when the well region of the substrate is p-type (or the doped regions have 122 and 124 are n-type), the gate electrode 137 includes p type-metal work function materials, such as ruthenium, palladium, platinum, cobalt, nickel, conductive metal oxide, or other suitable materials.

The gate electrode 137 and the carrier-transmission barrier layer 108 can be configured to reduce the velocity of carriers, thereby achieving a slower swing.

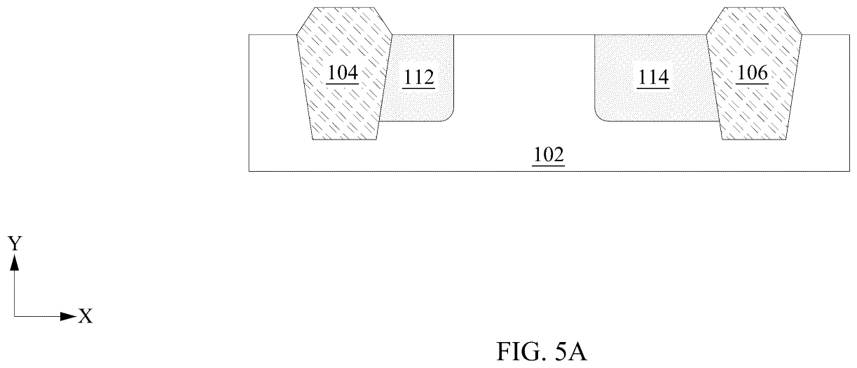

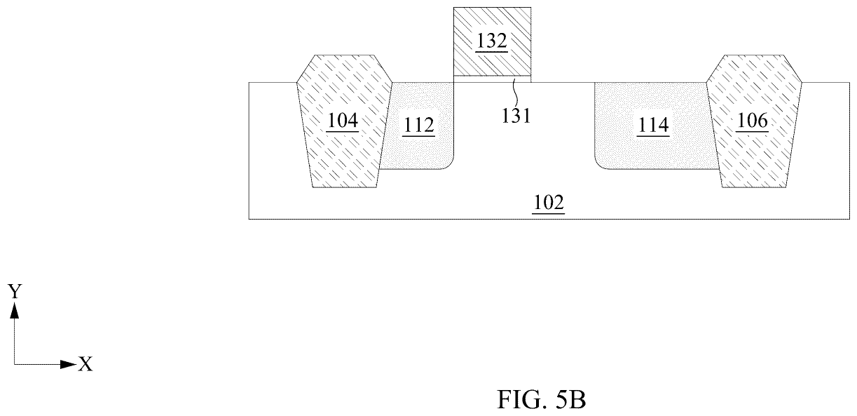

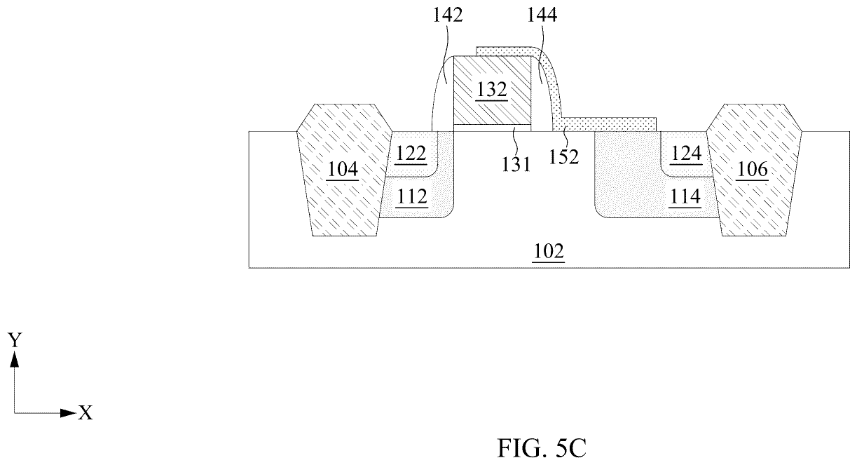

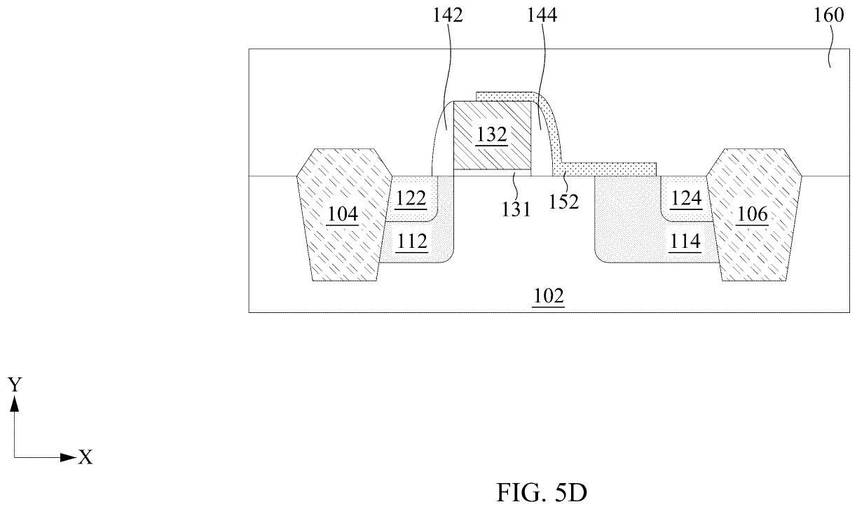

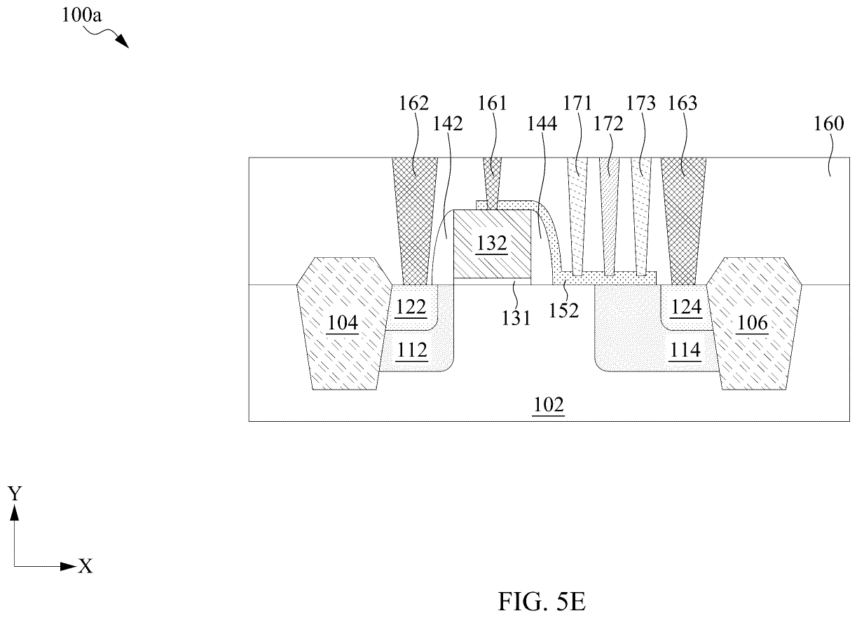

FIG. 5A, FIG. 5B, FIG. 5C, FIG. 5D, and FIG. 5E illustrate various stages of manufacturing a semiconductor device, in accordance with some embodiments of the present disclosure.

Referring to FIG. 5A, the substrate 102 is provided. The isolation structures 104 and 106 are formed. In some embodiments, a local oxidation of silicon (LOCOS) technique is performed to form the isolation structures 104 and 106. In other embodiments, the isolation structures 104 and 106 include the STI structure. In this embodiment, a portion of the substrate 102 is removed to from trenches, and a liner layer is formed within the trenches. Next, a dielectric material is deposited to fill the trenches and over the substrate 102. A chemical mechanical polishing (CMP) technique is performed to planarize the STI and the substrate 102. The lightly doped regions 112 and 114 are formed within the substrate 102 and abuts the isolation structures 104 and 106, respectively.

Referring to FIG. 5B, the gate dielectric 131 and gate electrode 132 are formed on the substrate 102. The gate dielectric 131 and the gate electrode 132 may be formed by a deposition technique, such as chemical vapor deposition (CVD), physical vapor deposition (PVD), atomic layer deposition (ALD), or other suitable techniques.

Referring to FIG. 5C, the spacers 142 and 144 are formed on the sidewalls of the gate electrode 132. The etch stop layer 152 is conformally formed on the gate electrode 132, the spacer 144, and the substrate 102. The spacer 142, spacer 144, and the etch stop layer 152 may be formed by a deposition technique, such as CVD, PVD, ALD, or other suitable techniques. The doped regions 122 and 124 are formed within the substrate 102. In some embodiments, the location of the doped regions 122 and 124 may be defined by the upper of the substrate 102 which is a region exposed by the spacer 142 and the etch stop layer 152.

Referring to FIG. 5D, the ILD 160 is formed to cover the substrate 102 and the gate electrode 132. In some embodiments, the ILD 160 may be formed by a deposition technique, such as CVD, PVD, ALD, or other suitable techniques.

Referring to FIG. 5E, the conductive contacts 161, 162, and 163 are formed on the gate electrode 132, doped region 122, and doped region 124, respectively. The field plates 171, 172, and 173 are formed on the etch stop layer 152. In some embodiments, one or more etching techniques are performed to remove a portion of the ILD 160 and the etch stop layer 152. Openings (not shown) are formed. Next, a barrier layer, a seed layer, a conductive material, and/or other suitable materials are deposited to fill the openings, thereby forming the conductive contacts 161, 162, and 163 as well as the field plates 171, 172, and 173. The conductive contacts 161, 162, and 163 as well as the field plates 171, 172, and 173 are formed by PVD, CVD, ALD, and other suitable techniques. Next, a CMP technique may be performed to planarize the ILD 160, the conductive contacts 161, 162, and 163 as well as the field plates 171, 172, and 173. As a result, a semiconductor device (e.g., the semiconductor device 100a) is produced.

In some embodiments, at the stage prior to that shown in FIG. 5B, a portion of the substrate 102 may be removed to form a trench (or opening). Next, an amorphous semiconductor material or polycrystalline semiconductor material may be formed within the trench to produce the carrier-transmission barrier layer 108. Next, the gate electrode 137 may be formed over the carrier-transmission barrier layer 108. The processes as shown in FIGS. 5C to 5E may be performed to produce the semiconductor device 100d.

Although FIGS. 5A to 5E illustrates that the gate electrode 132 is formed prior to the formation of the doped regions 122 and 124, the present disclosure is not intended to be limiting. In other embodiments, a sacrifice gate may be formed and then replaced by a metal gate, thereby defining the gate electrode 132.

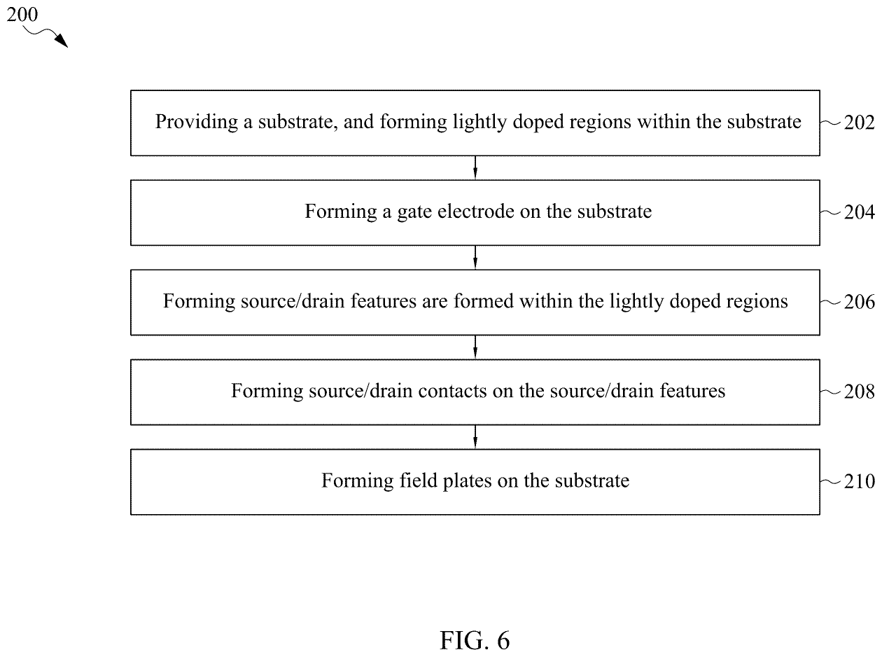

FIG. 6 is a flow chart illustrating a method 200 for manufacturing a semiconductor device according to various aspects of the present disclosure.

The method 200 begins with operation 202 in which a substrate is provided. An isolation structure is formed. Lightly doped regions are formed within the substrate.

The method 200 continues with operation 204 in which a gate electrode is formed on the substrate.

The method 200 continues with operation 206 in which source/drain features are formed within the lightly doped regions.

The method 200 continues with operation 208 in which source/drain contacts are formed on the source/drain features.

The method 200 continues with operation 210 in which field plates are formed on the substrate. Abutting two of the field plates are configured to receive voltages of different electrical polarities.

The method 200 is merely an example, and is not intended to limit the present disclosure beyond what is explicitly recited in the claims. Additional operations can be provided before, during, and after the method 200, and some operations described can be replaced, eliminated, or moved around for additional embodiments of the method.

Some embodiments of the present disclosure provide a semiconductor device. The semiconductor device includes a substrate, a gate electrode, a source/drain contact, a first field plate, and a second field plate. The gate electrode is disposed on the substrate. The source/drain contact is disposed on the substrate. The first field plate and the second field plate are disposed between the source/drain contact and the gate electrode. The first field plate is configured to receive a voltage of a first electrical polarity, and the second field plate is configured to receive a voltage of a second electrical polarity different from the first electrical polarity.

Some embodiments of the present disclosure provide a semiconductor device. The semiconductor device includes a substrate, a gate electrode, a source/drain contact, and a first field plate. The gate electrode is disposed on the substrate. The source/drain contact is disposed on the substrate. The first field plate is disposed between the source/drain contact and the gate electrode. Each the gate electrode and the source/drain contact is configured to receive a voltage of a first electrical polarity. The first field plate is configured to receive a voltage of a second electrical polarity different from the first electrical polarity.

Some embodiments of the present disclosure provide a method of manufacturing a semiconductor device. The method includes: forming a substrate; forming a gate electrode on the substrate; forming a source/drain contact on the substrate; and forming a first field plate and a second field plate on the substrate, wherein the first field plate and the second field plate are disposed between the source/drain contact and the gate electrode, and the first field plate is configured to receive a voltage of a first electrical polarity, and the second field plate is configured to receive a voltage of a second electrical polarity different from the first voltage.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate electrode disposed on the substrate;
a source/drain contact disposed on the substrate; and
a first field plate and a second field plate disposed between the source/drain contact and the gate electrode,
wherein the first field plate is configured to receive a voltage of a first electrical polarity, and the second field plate is configured to receive a voltage of a second electrical polarity different from the first electrical polarity.

2. The semiconductor device of claim 1, wherein the first field plate is disposed between the second field plate and the gate electrode, and the gate electrode is configured to receive the voltage of the second electrical polarity.

3. The semiconductor device of claim 1, further comprising:
a third field plate, wherein the second field plate is disposed between the first field plate and the third field plate, and the third field plate is configured to receive the voltage of the first electrical polarity.

4. The semiconductor device of claim 3, further comprising:
a lightly doped region within the substrate, wherein the second field plate and the third field plate vertically overlap the lightly doped region.

5. The semiconductor device of claim 1, wherein the gate electrode comprises a first work function metal layer with a first conductive type and a second work function metal layer with a second conductive type different from the first conductive type.

6. The semiconductor device of claim 5, wherein the second work function metal layer is disposed between the first field plate and the first work function metal layer.

7. The semiconductor device of claim 1, further comprising:
a carrier-transmission barrier layer disposed within the substrate and under the gate electrode.

8. The semiconductor device of claim 7, wherein the carrier-transmission barrier layer comprises an amorphous semiconductor material.

9. The semiconductor device of claim 8, further comprising:
source/drain features within the substrate and having a first conductive type, wherein and the gate electrode comprises a work function metal layer with a second conductive type different from the first conductive type.

10. The semiconductor device of claim 8, wherein a portion of the carrier-transmission barrier layer is free from vertically overlapping the gate electrode.

11. A semiconductor device, comprising:
a substrate;
a gate electrode disposed on the substrate;
a source/drain contact disposed on the substrate; and
a first field plate disposed between the source/drain contact and the gate electrode, wherein the gate electrode is configured to receive a first voltage of a first electrical polarity, and the first field plate is configured to receive a second voltage of a second electrical polarity different from the first electrical polarity.

12. The semiconductor device of claim 11, further comprising:
a second field plate disposed between the source/drain contact and the first field plate,
wherein the second field plate is configured to receive a third voltage of the first electrical polarity.

13. The semiconductor device of claim 12, further comprising:
a well region within the substrate with a first conductive type; and
a lightly doped region within the substrate and having a second conductive type different from the first conductive type,
wherein the second field plate vertically overlaps the lightly doped region.

14. The semiconductor device of claim 13, wherein the first field plate is free from vertically overlapping the lightly doped region.

15. The semiconductor device of claim 11, further comprising:
an amorphous semiconductor material disposed under the gate electrode.

16. The semiconductor device of claim 15, wherein the first field plate is free from vertically overlapping the amorphous semiconductor material.

17. The semiconductor device of claim 11, wherein the gate electrode comprises a first work function metal layer with a first conductive type and a second work function metal layer with a second conductive type different from the first conductive type.

18. A method of manufacturing a semiconductor device, comprising:
forming a substrate;
forming a gate electrode on the substrate;
forming a source/drain contact on the substrate; and
forming a first field plate and a second field plate on the substrate,
wherein the first field plate and the second field plate are disposed between the source/drain contact and the gate electrode, the first field plate is configured to receive a voltage of a first electrical polarity, and the second field plate is configured to receive a voltage of a second electrical polarity different from the first electrical polarity.

19. The method of claim 18, further comprising:
forming a third field plate, wherein the second field plate is disposed between the first field plate and the third field plate, and the third field plate is configured to receive the voltage of the first electrical polarity.

20. The method of claim 18, further comprising:
removing a portion of the substrate to form an opening; and
filling an amorphous semiconductor material within the opening,
wherein the gate electrode is disposed over the amorphous semiconductor material.
